(19) United States
(12) Patent Application Publication
(10) Pub. No.: US 2015/0109596 A1
(43) Pub. Date: Apr. 23, 2015

(54) METHOD AND SYSTEM FOR ACHIEVING AUTOMATIC COMPENSATION IN GLASS SUBSTRATE EXPOSURE PROCESS

(71) Applicant: Shenzhen China Star Optoelectronics Technology Co. Ltd., Shenzhen, Guangdong (CN)

(72) Inventors: Wende Huang, Shenzhen City (CN); Kai Shi, Shenzhen City (CN); Shuhan Zhang, Shenzhen City (CN)

(73) Assignee: Shenzhen China Star Optoelectronics Technology Co. Ltd., Shenzhen, Guangdong (CN)

(21) Appl. No.: 14/346,711

(22) PCT Filed: Jan. 9, 2014
(86) PCT No.: PCT/CN2014/070363

§ 371 Date: Mar. 21, 2014

(30) Foreign Application Priority Data
Oct. 23, 2013 (CN) 201310501656.7

(51) Int. Cl. G03F 7/20

(52) U.S. Cl. CPC G03F 7/70141
USPC 355/67

(57) ABSTRACT

The present invention discloses a system for achieving automatic compensation in glass substrate exposure process, including a measurement machine, a communication interface module and an exposure machine, wherein the measurement machine, for performing measurement on exposed glass substrate, and transmitting measured exposure shift data of each measurement point through communication interface module to a default storage area of exposure machine; and the exposure machine, for reading exposure shift data from each default storage area, obtaining a compensation value corresponding to each measurement point based on the exposure shift data and performing compensation processing on the glass substrate and each exposure point corresponding to each measurement point. The present invention also discloses a corresponding method. The present invention can improve compensation efficiency and accuracy of the exposure machine as save man power.

The present application claims priority of “METHOD AND SYSTEM FOR ACHIEVING AUTOMATIC COMPENSATION IN GLASS SUBSTRATE EXPOSURE PROCESS”, application number 201310501656.7 submitted to State Intellectual Property Office, People Republic of China dated Oct. 23, 2013.

### BACKGROUND OF THE INVENTION

1. Field of the Invention

The present invention relates to the field of thin film transistor liquid crystal display (TFT-LCD) techniques, and in particular to a method and system for achieving automatic compensation in glass substrate exposure process.

2. The Related Arts

An exposure machine is required in a lithographic process of the TFT-LCD manufacturing process. The exposure process is achieved by the exposure machine and the mask on a glass substrate coated with photo-resist film. In this step, the position accuracy of the exposure determines the alignment and manufacturing precision of the glass substrate in the subsequent manufacturing process. An imprecise the exposure position will cause the unmatchable pattern position in the next manufacturing process, which possibly leads to the transistors in the TFT substrate unable to conduct or the RGB pixel of the color filter (CF) substrate leaks. As such, during the cell process, the TFT substrate and the CF substrate may be unable to align and the yield rate of the cell process will be lowered.

Therefore, the controlling of the precision of the exposure position of the exposure machine is very important. In known technique, the measurement on the exposure position precision must be taken for the exposed glass substrate, and a re-exposure is performed according to the measurement. Two types of measurements are taken. The first type is the measurement on the total pitch of the first layer pattern exposed on the glass substrate, wherein the total pitch refers to the difference between the distance between two points in the mask design in a single direction and the distance between two points measured on the actual manufactured glass substrate. If the total pitch is greater than zero, the actual exposure pattern on the glass substrate is larger than the design. On the other hand, if the total pitch is less than zero, the actual exposure pattern on the glass substrate is smaller than the design. The second type is the measurement on the overlay of the subsequent lithographic process. In general, the first layer pattern exposed on the glass substrate is used as a basis, and the measurement of the relative size of the overlay. The exposure can perform compensate according to the measured total pitch or overlay data.

In known technique, the exposed glass substrate passes the subsequent process or machine to enter the measurement machine for measuring the total pitch or overlay data. After the measurement data is obtained, the operator inspects the data on the measurement machine and inputs to a compensation formula table to compute the compensation value. Then, the operator inputs the compensation value to the parameters of the software of the exposure machine to complete the compensation, and subsequently observes the measurement after the compensation.

As shown, the known technique has the following disadvantages. The first is the computation and the inputting of the compensation value must be conducted manually by an operator. As such, the risk of errors exists and abnormally exposed glass substrate may be produced when the errors are not discovered in time. For example, in an embodiment, 20 abnormally exposed glass substrates may be produced in 10 minutes with a 30-second period, and reprocessing is required, which results in wasting. In addition, the compensated glass substrate is seldom returned to the measurement machine for re-measurement, and the compensation effect cannot be known in time. To assure product quality, the operator must constantly confirm and compensate, which is time-consuming and unreliable in effect.

### SUMMARY OF THE INVENTION

The technical issue to be addressed by the present invention is to provide a method and system for achieving automatic compensation in glass substrate exposure process, able to improve the compensation efficiency and accuracy of the exposure machine as well as save man power.

The present invention provides a system for achieving automatic compensation in glass substrate exposure process, which comprises a measurement machine, and an exposure machine, communicating with measurement machine through communication interface module, wherein the measurement machine being configured to perform measurement on an exposed glass substrate, and transmit the measured exposure shift data of each measurement point through the communication interface module to a default storage area of the exposure machine; and the exposure machine, being configured to read exposure shift data from each default storage area and obtain a compensation value corresponding to each measurement point based on the exposure shift data of each measurement point and perform compensation processing on the glass substrate and each exposure point corresponding to each measurement point.

According to a preferred embodiment of the present invention, the measurement machine comprises: a measurement unit, being configured to perform measurement on the exposed glass substrate to obtain the exposure shift data of each measurement point on the glass substrate; a shift format determination unit, being configured to determine whether the shift data of each measurement point obtained by the measurement unit conforming a default format; a feedback file generation unit, being configured to generate a feedback file comprising the shift data of each measurement point after the shift format determination unit determining at least a part of shift data of each measurement point conforming to the default format; and a transmission unit, being configured to transmit the feedback file generated by the feedback file generation unit.

According to a preferred embodiment of the present invention, the feedback file comprises at least: a file created time, a measurement machine identification (ID), a glass substrate identification (ID), an x-direction shift of each measurement point, a y-direction shift of each measurement point, and a format determination result of each measurement point.

According to a preferred embodiment of the present invention, the measurement machine further comprises: a prompt unit, being configured to generate a warning prompt after the shift format determination unit determining the shift data of each measurement point not conforming to the default format.

According to a preferred embodiment of the present invention, the exposure machine comprises: a default storage area disposition unit, being configured to dispose a default storage area for the feedback file to provide the measurement machine to access and upload the feedback file; a compensation processing unit, being configured to perform exposure compensation processing on corresponding glass substrate based on the feedback file stored in the default storage area; and a mandatory inspection disposition unit, being configured to mark a mandatory inspection signal to a first glass substrate entering the exposure machine subsequently after the compensation on the glass substrate.

According to a preferred embodiment of the present invention, the compensation processing unit further comprises: a feedback file reading unit, being configured to read a stored feedback file when detecting the file being stored into the default storage area; a feedback file format determination unit, being configured to determine whether the feedback file read by the feedback file reading unit conforming to a default format, the default format comprising a file type, a file name format and a content format; a feedback file analysis unit, being configured to perform analysis on the feedback file conforming to the default format, obtain the glass substrate ID and obtain previous exposure stage of the glass substrate based on the obtained glass substrate ID; and to compute automatically a compensation corresponding to each measurement point based on the coordination shift of each measurement point in the feedback file; a threshold comparison unit, being configured to compare the compensation corresponding to each measurement point against a default threshold; and a compensation unit, being configured to perform compensation processing on the exposure point corresponding to the measurement point on the glass substrate with the compensation larger than the default threshold.

According to a preferred embodiment of the present invention, the compensation processing unit further comprises: a warning unit, being configured to generate a warning prompt when the feedback file format determination unit determining the feed file format not conforming to the default format.

According to a preferred embodiment of the present invention, the default storage area disposed by the default storage area disposition unit is a data folder of an FTP server accessible to the measurement machine.

Correspondingly, another embodiment of the present invention provides a system for achieving automatic compensation in glass substrate exposure process, which comprises a measurement machine, and an exposure machine, communicating with measurement machine through communication interface module, wherein the measurement machine being configured to perform measurement on an exposed glass substrate, and transmit the measured exposure shift data of each measurement point through the communication interface module to a default storage area of the exposure machine; and the exposure machine, being configured to read exposure shift data from each default storage area and obtain a compensation value corresponding to each measurement point based on the exposure shift data of each measurement point and perform compensation processing on the glass substrate and each exposure point corresponding to each measurement point; wherein the measurement machine comprising: a measurement unit, being configured to perform measurement on the exposed glass substrate to obtain the exposure shift data of each measurement point on the glass substrate; a shift format determination unit, being configured to determine whether the shift data of each measurement point obtained by the measurement unit conforming a default format; a feedback file generation unit, being configured to generate a feedback file comprising the shift data of each measurement point after the shift format determination unit determining at least a part of shift data of each measurement point conforming to the default format; and a transmission unit, being configured to transmit the feedback file generated by the feedback file generation unit.

According to a preferred embodiment of the present invention, the feedback file comprises at least: a file created time, a measurement machine identification (ID), a glass substrate identification (ID), an x-direction shift of each measurement point, a y-direction shift of each measurement point, and a format determination result of each measurement point.

According to a preferred embodiment of the present invention, the measurement machine further comprises: a prompt unit, being configured to generate a warning prompt after the shift format determination unit determining the shift data of each measurement point not conforming to the default format.

According to a preferred embodiment of the present invention, the exposure machine comprises: a default storage area disposition unit, being configured to dispose a default storage area for the feedback file to provide the measurement machine to access and upload the feedback file; a compensation processing unit, being configured to perform exposure compensation processing on corresponding glass substrate based on the feedback file stored in the default storage area; and a mandatory inspection disposition unit, being configured to mark a mandatory inspection signal to a first glass substrate entering the exposure machine subsequently after the compensation on the glass substrate.

According to a preferred embodiment of the present invention, the compensation processing unit further comprises: a feedback file reading unit, being configured to read a stored feedback file when detecting the file being stored into the default storage area; a feedback file format determination unit, being configured to determine whether the feedback file read by the feedback file reading unit conforming to a default format, the default format comprising a file type, a file name format and a content format; a feedback file analysis unit, being configured to perform analysis on the feedback file conforming to the default format, obtain the glass substrate ID and obtain previous exposure stage of the glass substrate based on the obtained glass substrate ID; and to compute automatically a compensation corresponding to each measurement point based on the coordination shift of each measurement point in the feedback file; a threshold comparison unit, being configured to compare the compensation corresponding to each measurement point against a default threshold; and a compensation unit, being configured to perform compensation processing on the exposure point corresponding to the measurement point on the glass substrate with the compensation larger than the default threshold.

According to a preferred embodiment of the present invention, the compensation processing unit further comprises: a warning unit, being configured to generate a warning prompt when the feedback file format determination unit determining the feed file format not conforming to the default format.

According to a preferred embodiment of the present invention, the default storage area disposed by the default storage area disposition unit is a data folder of an FTP server accessible to the measurement machine.

Correspondingly, another embodiment of the present invention provides a method for achieving automatic compensation in glass substrate exposure process, which comprises the following steps: a measurement machine performing measurement on an exposed glass substrate, and transmitting the measured exposure shift data of each measurement point through a communication interface module to a default storage area of an exposure machine; and the exposure machine reading exposure shift data from each default storage area and obtaining a compensation value corresponding to each measurement point based on the exposure shift data of each measurement point and performing compensation processing on the glass substrate and each exposure point corresponding to each measurement point.

According to a preferred embodiment of the present invention, the step of a measurement machine performing measurement on an exposed glass substrate, and transmitting the measured exposure shift data of each measurement point through a communication interface module to a default storage area of an exposure machine further comprises: performing measurement on the exposed glass substrate to obtain the exposure shift data of each measurement point on the glass substrate; determining whether the shift data of each measurement point obtained conforming a default format; generating a feedback file comprising the shift data of each measurement point after determining at least a part of shift data of each measurement point conforming to the default format, wherein the feedback file comprising at least: a file created time, a measurement machine identification (ID), a glass substrate identification (ID), an x-direction shift of each measurement point, a y-direction shift of each measurement point, and a format determination result of each measurement point; and transmitting the feedback file to the default storage area of the exposure machine.

According to a preferred embodiment of the present invention, the step of the exposure machine reading exposure shift data from each default storage area and obtaining a compensation value corresponding to each measurement point based on the exposure shift data of each measurement point and performing compensation processing on the glass substrate and each exposure point corresponding to each measurement point further comprises: reading a stored feedback file when detecting the file being stored into the default storage area; determining whether the feedback file conforming to a default format, wherein the default format comprising a file type, a file name format and a content format; performing analysis on the feedback file conforming to the default format and computing automatically a compensation corresponding to each measurement point based on the coordination shift of each measurement point in the feedback file; comparing the compensation corresponding to each measurement point against a default threshold; and performing compensation processing on the exposure point corresponding to the measurement point on the glass substrate with the compensation larger than the default threshold.

According to a preferred embodiment of the present invention, the method further comprises the step of: disposing a default storage area for the feedback file to provide the measurement machine to access and upload the feedback file; wherein the disposed default storage area is a data folder of an FTP server accessible to the measurement machine.

According to a preferred embodiment of the present invention, the method further comprises the step of: marking a mandatory inspection signal to a first glass substrate entering the exposure machine subsequently after the compensation on the glass substrate.

The efficacy of the present invention is that to be distinguished from the state of the art. Through the uploading of the feedback file comprising exposure shift data of the glass substrate by the measurement machine to the exposure machine, the exposure machine of the present invention can automatically achieve exposure compensation on the glass substrate according to the feedback file to effectively increase the compensation efficiency and accuracy of the exposure machine. As such, the exposure quality and stability of the glass substrate is increased and man power is saved.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the structure of a system for achieving automatic compensation in glass substrate exposure process according to the present invention;

FIG. 2 is schematic view showing the structure of an embodiment of a measurement machine shown in FIG. 1;

FIG. 3 is a schematic view showing the feedback file of an embodiment of a system for achieving automatic compensation in glass substrate exposure process according to the present invention;

FIG. 4 is a schematic view showing the structure of an embodiment of an exposure machine shown in FIG. 1;

FIG. 5 is a schematic view showing the structure of an embodiment of a compensation processing unit shown in FIG. 3;

FIG. 6 is a flowchart of an embodiment of a system for achieving automatic compensation in glass substrate exposure process according to the present invention;

FIG. 7 is a flowchart of an embodiment of the measurement machine of a system for achieving automatic compensation in glass substrate exposure process according to the present invention; and

FIG. 8 is a flowchart of an embodiment of the exposure machine of a system for achieving automatic compensation in glass substrate exposure process according to the present invention.

### DETAILED DESCRIPTION OF THE PREFERRED EMBODIMENTS

The following refers to drawings and embodiment for detailed description of the present invention.

Referring to FIG. 1, FIG. 1 is a schematic view showing the structure of a system for achieving automatic compensation in glass substrate exposure process according to the present invention. As shown in FIG. 1, the system comprises a measurement machine 1, and an exposure machine 2, communicating with measurement machine through communication interface module 3.

The measurement machine 1 is configured to perform measurement on an exposed glass substrate, and transmit the measured exposure shift data of each measurement point through the communication interface module 3 to a default storage area of the exposure machine.

The exposure machine 2 is configured to read exposure shift data from each default storage area and obtain a compensation value corresponding to each measurement point based on the exposure shift data of each measurement point and perform compensation processing on the glass substrate and each exposure point corresponding to each measurement point.

The communication interface module (CIM) 3 is for realizing the communication between the measurement machine 1 and the exposure machine 2. The CIM may comprise a plurality of connection cables and corresponding control modules. For example, in an embodiment, the CIM comprises a coaxial cable and UTP, wherein the coaxial cable is for transmitting control commands and the UTP is for transmitting specific data file, and the feedback file is transmitted through the UTP. Specifically, an IP address must be assigned to the ports of the measurement machine and the exposure machine to ensure the communication stability between the measurement machine 1 and the exposure machine 2.

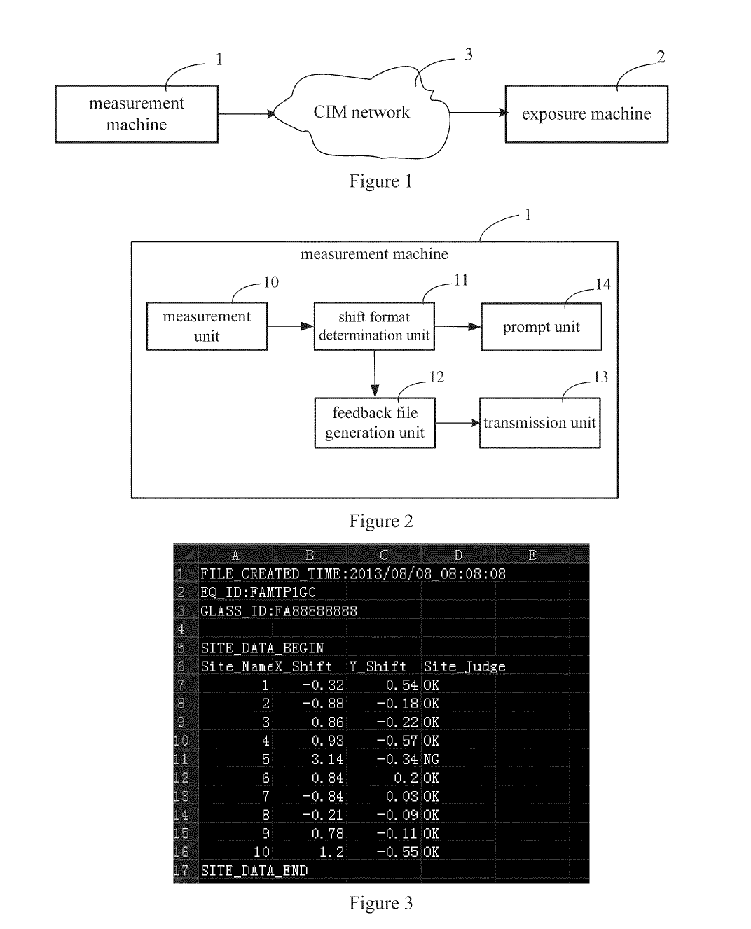

Referring to FIG. 2, FIG. 2 is schematic view showing the structure of an embodiment of a measurement machine shown in FIG. 1. In the instant embodiment, the measurement machine 1 comprises:

A measurement unit 10, which is configured to perform measurement on the exposed glass substrate to obtain the exposure shift data of each measurement point on the glass substrate;

A shift format determination unit 11, which is configured to determine whether the shift data of each measurement point obtained by the measurement unit 10 conforming a default format; the shift format determination unit 11 is able to prevent the erroneous compensation by exposure machine 2 caused by the erroneous measurement data the measurement machine 1;

A feedback file generation unit 12, which is configured to generate a feedback file comprising the shift data of each measurement point after the shift format determination unit 11 determining at least a part of shift data of each measurement point conforming to the default format;

A prompt unit 14, which is configured to generate a warning prompt after the shift format determination unit 11 determining the shift data of each measurement point not conforming to the default format; and

A transmission unit 13, which is configured to transmit the feedback file generated by the feedback file generation unit 12 through the CIM 3 to the default storage area of the exposure machine 2. The default storage area is a data folder of an FTP server accessible to the measurement machine.

It should be noted that, to avoid the situation where the feedback file is unable to be uploaded to the exposure machine 2 because of disconnected network or malfunctioning FTP server, the measurement machine 1 further comprises a unit for monitoring whether the feedback file being successfully transmitted to alarm the related staff when the feedback file is unable to transmit successfully.

FIG. 3 shows an embodiment of the feedback file of FIG. 2, wherein the feedback file can be a csv format file, named according to the glass substrate ID, and comprises at least: a file created time (FILE_CREATED_TIME), a measurement machine identification (EQ_ID), a glass substrate identification (GLASS_ID), an x-direction shift (X_Shift) of each measurement point, a y-direction shift (Y_Shift) of each measurement point, and a format determination result (OK or NO) of each measurement point. In the instant embodiment, the shifts in the x-direction and y-direction of 10 measurement points are lists. It should be noted that it is only for illustrative purpose, instead of restrictive. For example, in other embodiments, the feedback file can also be created in other distinguishable format, such as, TXT format. The same format of feedback file allows the present invention to be applied to various exposure machines and measurement machines.

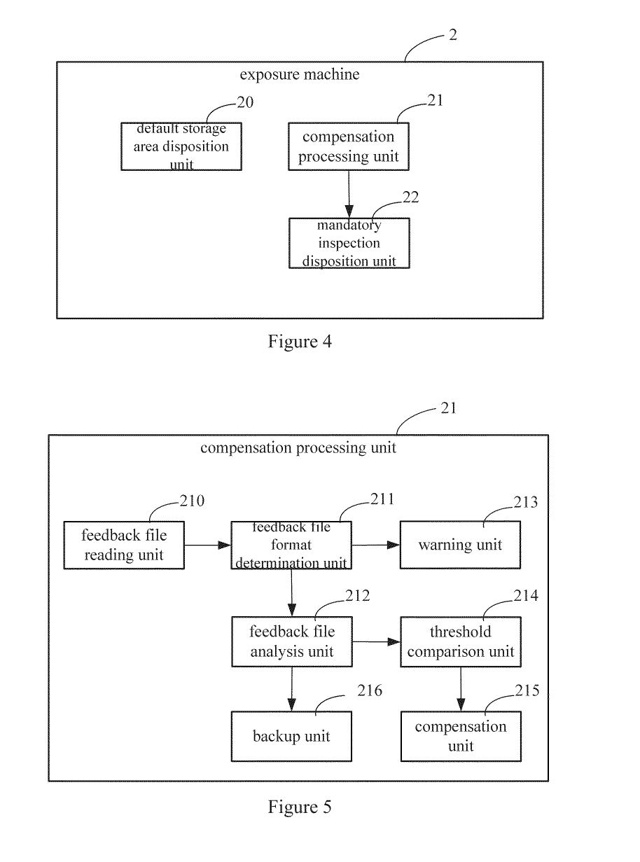

FIG. 4 is a schematic view showing the structure of an embodiment of an exposure machine shown in FIG. 1. In the instant embodiment, the exposure machine 2 comprises:

A default storage area disposition unit 20, which is configured to dispose a default storage area for the feedback file to provide the measurement machine to access and upload the feedback file; specifically, the default storage area is a data folder of an FTP server accessible to the measurement machine; and the FTP server can be realized with a internet information service (IIS) provided by Microsoft or with FileZilla Server of other providers;

A compensation processing unit 21, which is configured to perform exposure compensation processing on corresponding glass substrate based on the feedback file stored in the default storage area; and

A mandatory inspection disposition unit 22, which is configured to mark a mandatory inspection signal to a first glass substrate entering the exposure machine subsequently after the compensation on the glass substrate.

Specifically, as shown in FIG. 5, the compensation processing unit further comprises:

A feedback file reading unit 210, which is configured to read a stored feedback file when detecting the file being stored into the default storage area;

A feedback file format determination unit 211, which is configured to determine whether the feedback file read by the feedback file reading unit 210 conforming to a default format, the default format comprising a file type, a file name format and a content format; in other words, to determine whether the feedback file is stored as CSV format, named according to the glass substrate ID and whether the file created time, the measurement machine ID, the glass substrate ID, the x-direction shift and y-direction shift of each measurement point, and the format determination result of each measurement point are included in the feedback file;

A feedback file analysis unit 212, which is configured to perform analysis on the feedback file conforming to the default format, obtain the glass substrate ID and obtain previous exposure stage of the glass substrate based on the obtained glass substrate ID; and to compute automatically a compensation corresponding to each measurement point based on the coordination shift of each measurement point in the feedback file;

A warning unit 213, which is configured to generate a warning prompt when the feedback file format determination unit 211 determining the feed file format not conforming to the default format.

A threshold comparison unit 214, which is configured to compare the compensation corresponding to each measurement point against a default threshold;

A compensation unit 215, which is configured to perform compensation processing on the exposure point corresponding to the measurement point on the glass substrate with the compensation larger than the default threshold; specifically, the compensation unit 215 performs the compensation to the exposure point according to the corresponding compensation value, i.e., to perform partial exposure on the glass substrate according to the compensation value; and

A backup unit 216, which configured to back up the compensation information before each compensation so that the most recent compensation point can be restored when a compensation value is erroneous.

It should be noted that in the present invention, to prevent a single error from causing the entire system to break down, some function units of the measurement machine 1 and the exposure machine 2 may be optional. For example, in other embodiments, the shift format determination unit 11 and prompt unit 14 of the measurement machine 1, and the feedback format determination unit 211 and the warning unit 213 of the exposure machine 2 are all disposed with an enable/disable option to provide the user to adjust the system according to actual application for optimal deployment.

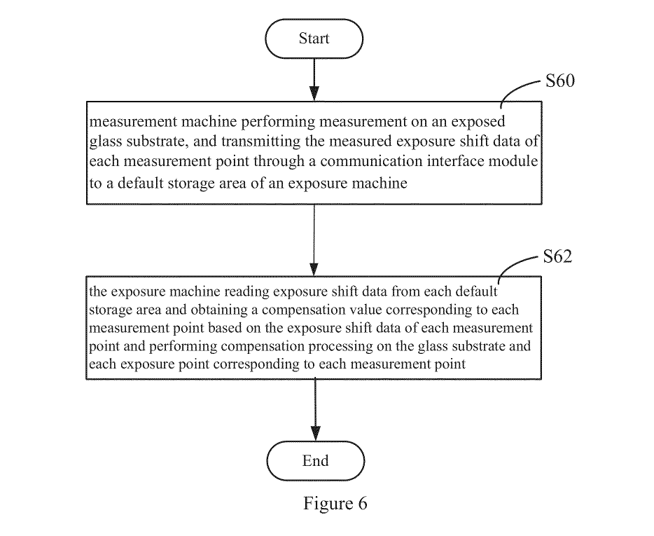

FIG. 6 is a flowchart of an embodiment of a system for achieving automatic compensation in glass substrate exposure process according to the present invention. In the instant embodiment, the method comprises the following steps:

Step S60: measurement machine performing measurement on an exposed glass substrate, and transmitting the measured exposure shift data of each measurement point through a communication interface module to a default storage area of an exposure machine; and

Step S62: the exposure machine reading exposure shift data from each default storage area and obtaining a compensation value corresponding to each measurement point based on the exposure shift data of each measurement point and performing compensation processing on the glass substrate and each exposure point corresponding to each measurement point.

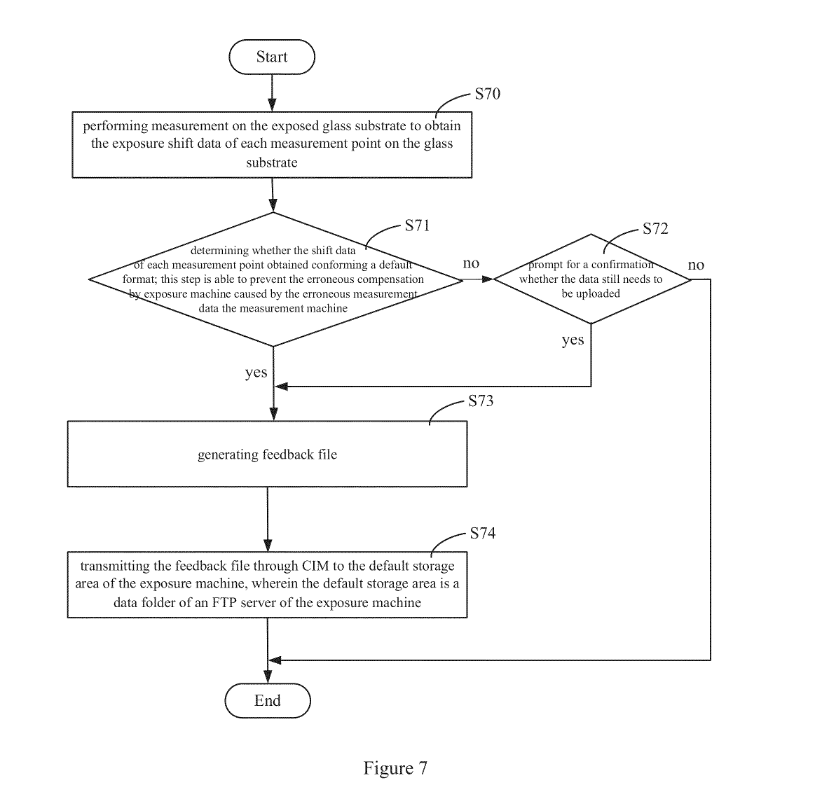

FIG. 7 is a flowchart of an embodiment of the measurement machine of a system for achieving automatic compensation in glass substrate exposure process according to the present invention. In the instant embodiment, the operation of the measurement machine comprises the following steps:

Step S70: performing measurement on the exposed glass substrate to obtain the exposure shift data of each measurement point on the glass substrate;

Step S71: determining whether the shift data of each measurement point obtained conforming a default format; this step is able to prevent the erroneous compensation by exposure machine caused by the erroneous measurement data the measurement machine;

If the result from the determination is that at least a part of shift data of each measurement point conforming to the default format, the process proceeds to step S73; otherwise, the process continues with step S72, wherein step S72 is to prompt for a confirmation whether the data still needs to be uploaded; if so, proceed to step S73; otherwise, the process terminates.

Step S73: generating a feedback file comprising the shift data of each measurement point, wherein the feedback file comprising at least: a file created time, a measurement machine identification (ID), a glass substrate identification (ID), an x-direction shift of each measurement point, a y-direction shift of each measurement point, and a format determination result of each measurement point; and

Step S74: transmitting the feedback file through CIM to the default storage area of the exposure machine, wherein the default storage area is a data folder of an FTP server of the exposure machine.

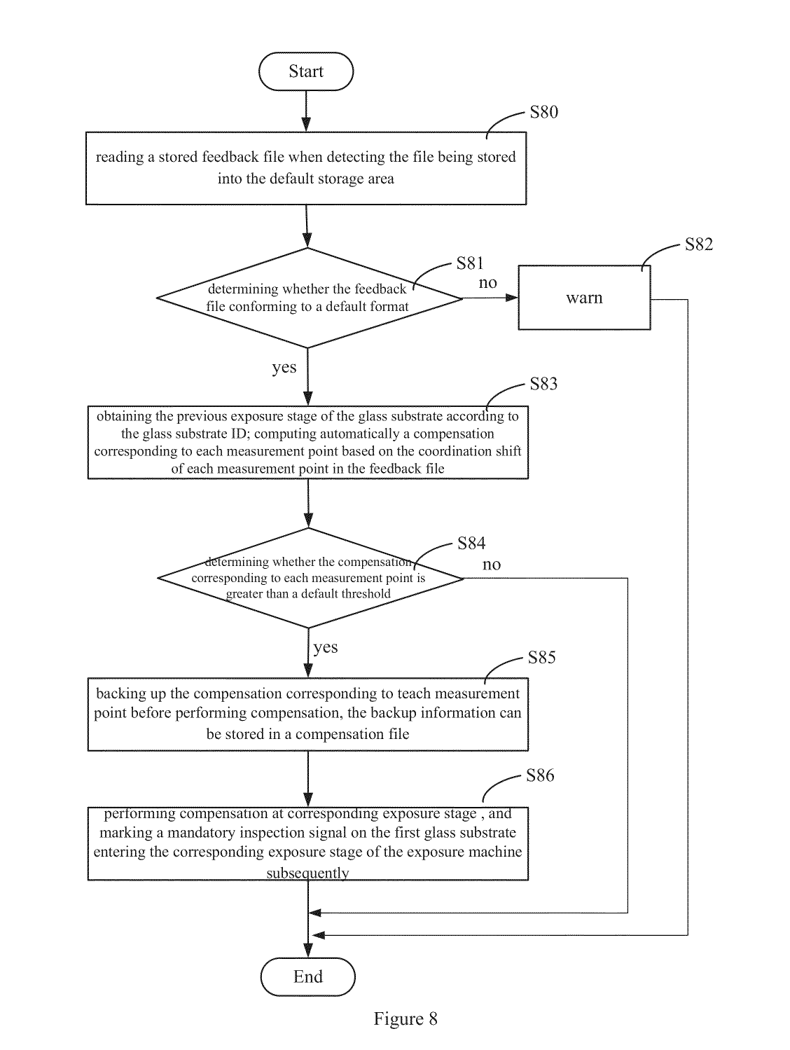

FIG. 8 is a flowchart of an embodiment of the exposure machine of a system for achieving automatic compensation in glass substrate exposure process according to the present invention. In the instant embodiment, the operation of the exposure machine comprises the following steps:

Step S80: reading a stored feedback file when detecting the file being stored into the default storage area;

Step S81: determining whether the feedback file conforming to a default format, wherein the default format comprising a file type, a file name format and a content format; if the result from the determination is that feedback conforms to the default format, the process proceeds to step S83; otherwise, the process continues with step S82, wherein step S82 is to warn and to terminate the process; step 81 can prevent the software of the exposure machine from shutting down caused by erroneous file format uploaded by the measurement machine or by other files erroneously placed in to the data folder;

Step S83: performing analysis on the feedback file conforming to the default format to obtain the glass substrate ID, and obtain the previous exposure stage (in general, every exposure being disposed with a left and a right exposure stage) of the glass substrate according to the glass substrate ID; and then computing automatically a compensation corresponding to each measurement point based on the coordination shift of each measurement point in the feedback file;

Step S84: comparing the compensation corresponding to each measurement point against a default threshold to determine whether the compensation corresponding to each measurement point is greater than a default threshold; if so, the process proceeds to step S85; otherwise, the process terminates; specifically, in an embodiment, the threshold can be set as 1 um, and the measurement point with compensation lower than 1 um will not be compensated; as such, the compensation efficiency can be improved;

Step S85: backing up the compensation corresponding to teach measurement point before performing compensation, the backup information can be stored in a compensation file; and

Step S86: at the corresponding exposure stage of the exposure machine, performing compensation processing on the exposure point corresponding to the measurement point on the glass substrate with the compensation larger than the default threshold; the compensation computation and the compensation are functions of the exposure, and the staff only need to set the correspondence between the measurement point and the exposure point in advance; specifically, the compensation can be performed with corresponding compensation to the exposure point; i.e., a partial re-exposure to the glass substrate according to the compensation. The details will not be repeated here.

In addition, after compensation, the first glass substrate entering the corresponding exposure stage of the exposure machine subsequently after the compensation on the glass substrate is marked with a mandatory inspection signal. The mandatory inspection signal is stored in CIM, such as, an address of PLC address of CIM can be allocated for storing to provide the measurement inspection equipment for accessing to inspect on the glass substrate.

The advantage of the present invention is that to be distinguished from the state of the art. Through the uploading of the feedback file comprising exposure shift data of the glass substrate by the measurement machine to the exposure machine, the exposure machine of the present invention can automatically achieve exposure compensation on the glass substrate according to the feedback file to effectively increase the compensation efficiency and accuracy of the exposure machine. As such, the exposure quality and stability of the glass substrate is increased and man power is saved.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A system for achieving automatic compensation in glass substrate exposure process, which comprises: a measurement machine, and an exposure machine, communicating with measurement machine through communication interface module, wherein:
the measurement machine being configured to perform measurement on an exposed glass substrate, and transmit the measured exposure shift data of each measurement point through the communication interface module to a default storage area of the exposure machine; and
the exposure machine, being configured to read exposure shift data from each default storage area and obtain a compensation value corresponding to each measurement point based on the exposure shift data of each measurement point and perform compensation processing on the glass substrate and each exposure point corresponding to each measurement point.

2. The system for achieving automatic compensation in glass substrate exposure process as claim 1, wherein the measurement machine comprises:
a measurement unit, being configured to perform measurement on the exposed glass substrate to obtain the exposure shift data of each measurement point on the glass substrate;
a shift format determination unit, being configured to determine whether the shift data of each measurement point obtained by the measurement unit conforming a default format;
a feedback file generation unit, being configured to generate a feedback file comprising the shift data of each measurement point after the shift format determination unit determining at least a part of shift data of each measurement point conforming to the default format; and
a transmission unit, being configured to transmit the feedback file generated by the feedback file generation unit.

3. The system for achieving automatic compensation in glass substrate exposure process as claimed in claim 2, wherein the feedback file comprises at least: a file created time, a measurement machine identification (ID), a glass substrate identification (ID), an x-direction shift of each measurement point, a y-direction shift of each measurement point, and a format determination result of each measurement point.

4. The system for achieving automatic compensation in glass substrate exposure process as claimed in claim 2, wherein the measurement machine further comprises:
a prompt unit, being configured to generate a warning prompt after the shift format determination unit determining the shift data of each measurement point not conforming to the default format.

5. The system for achieving automatic compensation in glass substrate exposure process as claimed in claim 4, wherein the exposure machine comprises:
a default storage area disposition unit, being configured to dispose a default storage area for the feedback file to provide the measurement machine to access and upload the feedback file;
a compensation processing unit, being configured to perform exposure compensation processing on corresponding glass substrate based on the feedback file stored in the default storage area; and
a mandatory inspection disposition unit, being configured to mark a mandatory inspection signal to a first glass substrate entering the exposure machine subsequently after the compensation on the glass substrate.

6. The system for achieving automatic compensation in glass substrate exposure process as claimed in claim 5, wherein the compensation processing unit further comprises:
a feedback file reading unit, being configured to read a stored feedback file when detecting the file being stored into the default storage area;
a feedback file format determination unit, being configured to determine whether the feedback file read by the feedback file reading unit conforming to a default format, the default format comprising a file type, a file name format and a content format;
a feedback file analysis unit, being configured to perform analysis on the feedback file conforming to the default format, obtain the glass substrate ID and obtain previous exposure stage of the glass substrate based on the obtained glass substrate ID; and to compute automatically a compensation corresponding to each measurement point based on the coordination shift of each measurement point in the feedback file;
a threshold comparison unit, being configured to compare the compensation corresponding to each measurement point against a default threshold; and
a compensation unit, being configured to perform compensation processing on the exposure point corresponding to the measurement point on the glass substrate with the compensation larger than the default threshold.

7. The system for achieving automatic compensation in glass substrate exposure process as claimed in claim 6, wherein the compensation processing unit further comprises:
a warning unit, being configured to generate a warning prompt when the feedback file format determination unit determining the feed file format not conforming to the default format.

8. The system for achieving automatic compensation in glass substrate exposure process as claimed in claim 6, wherein the default storage area disposed by the default storage area disposition unit is a data folder of an FTP server accessible to the measurement machine.

9. A system for achieving automatic compensation in glass substrate exposure process, which comprises: a measurement machine, and an exposure machine, communicating with measurement machine through communication interface module, wherein:
the measurement machine being configured to perform measurement on an exposed glass substrate, and transmit the measured exposure shift data of each measurement point through the communication interface module to a default storage area of the exposure machine;
the exposure machine, being configured to read exposure shift data from each default storage area and obtain a compensation value corresponding to each measurement point based on the exposure shift data of each measurement point and perform compensation processing on the glass substrate and each exposure point corresponding to each measurement point;
wherein the measurement machine comprising:
a measurement unit, being configured to perform measurement on the exposed glass substrate to obtain the exposure shift data of each measurement point on the glass substrate;
a shift format determination unit, being configured to determine whether the shift data of each measurement point obtained by the measurement unit conforming a default format;
a feedback file generation unit, being configured to generate a feedback file comprising the shift data of each measurement point after the shift format determination unit determining at least a part of shift data of each measurement point conforming to the default format; and
a transmission unit, being configured to transmit the feedback file generated by the feedback file generation unit.

10. The system for achieving automatic compensation in glass substrate exposure process as claimed in claim 9, wherein the feedback file comprises at least: a file created time, a measurement machine identification (ID), a glass substrate identification (ID), an x-direction shift of each measurement point, a y-direction shift of each measurement point, and a format determination result of each measurement point.

11. The system for achieving automatic compensation in glass substrate exposure process as claimed in claim 10, wherein the measurement machine further comprises:
a prompt unit, being configured to generate a warning prompt after the shift format determination unit determining the shift data of each measurement point not conforming to the default format.

12. The system for achieving automatic compensation in glass substrate exposure process as claimed in claim 11, wherein the exposure machine comprises:
a default storage area disposition unit, being configured to dispose a default storage area for the feedback file to provide the measurement machine to access and upload the feedback file;
a compensation processing unit, being configured to perform exposure compensation processing on corresponding glass substrate based on the feedback file stored in the default storage area; and
a mandatory inspection disposition unit, being configured to mark a mandatory inspection signal to a first glass substrate entering the exposure machine subsequently after the compensation on the glass substrate.

13. The system for achieving automatic compensation in glass substrate exposure process as claimed in claim 12, wherein the compensation processing unit further comprises:
a feedback file reading unit, being configured to read a stored feedback file when detecting the file being stored into the default storage area;
a feedback file format determination unit, being configured to determine whether the feedback file read by the feedback file reading unit conforming to a default format, the default format comprising a file type, a file name format and a content format;
a feedback file analysis unit, being configured to perform analysis on the feedback file conforming to the default format, obtain the glass substrate ID and obtain previous exposure stage of the glass substrate based on the obtained glass substrate ID; and to compute automatically a compensation corresponding to each measurement point based on the coordination shift of each measurement point in the feedback file;
a threshold comparison unit, being configured to compare the compensation corresponding to each measurement point against a default threshold; and
a compensation unit, being configured to perform compensation processing on the exposure point corresponding to the measurement point on the glass substrate with the compensation larger than the default threshold.

14. The system for achieving automatic compensation in glass substrate exposure process as claimed in claim 13, wherein the compensation processing unit further comprises:
a warning unit, being configured to generate a warning prompt when the feedback file format determination unit determining the feed file format not conforming to the default format.

15. The system for achieving automatic compensation in glass substrate exposure process as claimed in claim 14, wherein the default storage area disposed by the default storage area disposition unit is a data folder of an FTP server accessible to the measurement machine.

16. A method for achieving automatic compensation in glass substrate exposure process, which comprises the following steps:
a measurement machine performing measurement on an exposed glass substrate, and transmitting the measured exposure shift data of each measurement point through a communication interface module to a default storage area of an exposure machine; and
the exposure machine reading exposure shift data from each default storage area and obtaining a compensation value corresponding to each measurement point based on the exposure shift data of each measurement point and performing compensation processing on the glass substrate and each exposure point corresponding to each measurement point.

17. The method for achieving automatic compensation in glass substrate exposure process as claimed in claim 17, wherein the step of a measurement machine performing measurement on an exposed glass substrate, and transmitting the measured exposure shift data of each measurement point through a communication interface module to a default storage area of an exposure machine further comprises:
performing measurement on the exposed glass substrate to obtain the exposure shift data of each measurement point on the glass substrate;
determining whether the shift data of each measurement point obtained conforming a default format;
generating a feedback file comprising the shift data of each measurement point after determining at least a part of shift data of each measurement point conforming to the default format, wherein the feedback file comprising at least: a file created time, a measurement machine identification (ID), a glass substrate identification (ID), an x-direction shift of each measurement point, a y-direction shift of each measurement point, and a format determination result of each measurement point; and
transmitting the feedback file to the default storage area of the exposure machine.

18. The method for achieving automatic compensation in glass substrate exposure process as claimed in claim 17, wherein the step of the exposure machine reading exposure shift data from each default storage area and obtaining a compensation value corresponding to each measurement point based on the exposure shift data of each measurement point and performing compensation processing on the glass substrate and each exposure point corresponding to each measurement point further comprises:
reading a stored feedback file when detecting the file being stored into the default storage area;
determining whether the feedback file conforming to a default format, wherein the default format comprising a file type, a file name format and a content format;
performing analysis on the feedback file conforming to the default format and computing automatically a compensation corresponding to each measurement point based on the coordination shift of each measurement point in the feedback file;
comparing the compensation corresponding to each measurement point against a default threshold; and
performing compensation processing on the exposure point corresponding to the measurement point on the glass substrate with the compensation larger than the default threshold.

19. The method for achieving automatic compensation in glass substrate exposure process as claimed in claim 18, further comprising the step of:
marking a mandatory inspection signal to a first glass substrate entering the exposure machine subsequently after the compensation on the glass substrate.
